(19) United States
(12) Patent Application Publication
(10) Pub. No.: US 2024/0274678 A1
(43) Pub. Date: Aug. 15, 2024

(54) THIN FILM TRANSISTOR AND MANUFACTURING METHOD FOR THE SAME

(71) Applicant: ADRC. CO. KR, Seoul (KR)

(72) Inventors: Seongbok Kang, Gumi-si (KR); Jin Jang, Seoul (KR)

(21) Appl. No.: 18/387,927

(22) Filed: Nov. 8, 2023

(30) Foreign Application Priority Data
Feb. 9, 2023 (KR) 10-2023-0017493

(51) Int. Cl. H01L 29/417; H01L 29/423; H01L 29/66; H01L 29/786

(52) U.S. Cl. CPC H01L 29/41733; H01L 29/42384; H01L 29/6675; H01L 29/78672

(57) ABSTRACT

A manufacturing method for a thin film transistor according to an exemplary embodiment includes a step of forming a buffer layer on a substrate, a step of forming a hydrogenated amorphous silicon layer on the buffer layer, a step of performing blue laser annealing on the hydrogenated amorphous silicon layer, and a step of forming a semiconductor layer by doping parts of the hydrogenated amorphous silicon layer with impurities, and in the step of performing blue laser annealing, dehydrogenation and crystallization are performed in the hydrogenated amorphous silicon layer.

### CROSS-REFERENCE TO RELATED APPLICATION(S)

This application claims priority to and the benefit of Korean Patent Application No. 10-2023-0017493 filed in the Korean Intellectual Property Office on Feb. 9, 2023, the entire contents of which are incorporated herein by reference.

### BACKGROUND

### (a) Field

The present disclosure relates to a thin film transistor and a manufacturing method for the same.

### (b) Description of the Related Art

Display panels such as liquid crystal display panels or organic light-emitting display panels include switching devices and/or thin film transistors (TFTs) which are three-terminal devices and serve as driving devices. Meanwhile, light-emitting devices or sensors include diodes which are two-terminal devices. One of the factors that determine the performance of such devices such as thin film transistors or diodes are semiconductors.

### SUMMARY

The present disclosure attempts to provide a thin film transistor and a manufacturing method for the thin film transistor, capable of simplifying the process, and reducing manufacturing cost, and maintaining high performance.

However, the effects of the exemplary embodiments are not limited to the above-described object, and they can be variously expanded without departing from the technical spirit and scope of the exemplary embodiments.

A manufacturing method for a thin film transistor according to an exemplary embodiment includes a step of forming a buffer layer on a substrate, a step of forming a hydrogenated amorphous silicon layer on the buffer layer, a step of performing blue laser annealing on the hydrogenated amorphous silicon layer, and a step of forming a semiconductor layer by doping parts of the hydrogenated amorphous silicon layer with impurities, and in the step of performing blue laser annealing, dehydrogenation and crystallization are performed in the hydrogenated amorphous silicon layer.

The dehydrogenation and the crystallization may be performed at the same time.

In the step of performing blue laser annealing, a blue laser may scan the semiconductor layer one time to three times.

The power of a blue laser which is used in the step of performing blue laser annealing may be 7 W or higher.

A blue laser which is used in the step of performing blue laser annealing may have a wavelength range from 400 nm to 500 nm.

The blue laser which is used in the step of performing blue laser annealing may have a wavelength range from 440 nm to 450 nm.

The scan speed of the blue laser may be 200 mm/s to 500 mm/s.

The step of performing blue laser annealing may be performed at 950° C. or higher.

The average grain size of the semiconductor layer formed through the blue laser annealing may be 50 nm to 200 nm.

The thickness of the semiconductor layer may be 50 nm to 800 nm.

The manufacturing method for the thin film transistor may further include a step of forming a gate electrode so as to overlap the semiconductor layer.

A thin film transistor according to an exemplary embodiment is manufactured by the manufacturing method for the thin film transistor.

The thin film transistor according to the exemplary embodiment includes a substrate, a buffer layer positioned on the substrate, a semiconductor layer that is positioned on the buffer layer and includes a first region, a second region, and a third region, a gate electrode that overlaps the second region of the semiconductor layer, a source electrode that is electrically coupled to the first region, and a drain electrode that is electrically coupled to the third region, and the average grain size of the semiconductor layer is 50 nm to 200 nm.

The thickness of the semiconductor layer may be 50 nm to 800 nm.

The gate electrode may be positioned on the semiconductor layer, and the thin film transistor may further include a gate insulating layer that is positioned between the gate electrode and the semiconductor layer.

The gate electrode may be positioned between the semiconductor layer and the substrate, and the thin film transistor may further include a gate insulating layer that is positioned between the gate electrode and the semiconductor layer.

The semiconductor layer may contain polysilicon.

According to the thin film transistor and the manufacturing method for the thin film transistor according to the exemplary embodiments, it is possible to simplify the process, and reduce the manufacturing cost, and provide high performance.

However, the effects of the exemplary embodiments are not limited to the above-described effects, and it is apparent that they can be variously expanded without departing from the spirit and scope of the present invention.

### BRIEF DESCRIPTION OF THE DRAWINGS

FIG. 1 is a cross-sectional view related to a thin film transistor according to an exemplary embodiment.

FIG. 2 is a cross-sectional view related to a thin film transistor according to an exemplary embodiment.

FIG. 3 to FIG. 8 are cross-sectional views according to a manufacturing method for the thin film transistor according to an exemplary embodiment, respectively.

FIG. 9 is a cross-sectional view according to a manufacturing method for a thin film transistor according to an exemplary embodiment.

FIG. 10 to FIG. 18 show experimental data of thin film transistors manufactured according to the exemplary embodiment.

### DETAILED DESCRIPTION OF THE EMBODIMENTS

In the following detailed description, only certain exemplary embodiments of the present invention have been shown and described, simply by way of illustration. The present invention can be variously implemented and is not limited to the following exemplary embodiments.

The drawings and description are to be regarded as illustrative in nature and not restrictive. Like reference numerals designate like elements throughout the specification.

Further, the accompanying drawings are provided for helping to easily understand exemplary embodiments disclosed in the present specification, and the technical spirit disclosed in the present specification is not limited by the accompanying drawings, and it will be appreciated that the present invention includes all of the modifications, equivalent matters, and substitutes included in the spirit and the technical scope of the present invention.

In addition, the size and thickness of each configuration shown in the drawings are arbitrarily shown for understanding and ease of description, but the present invention is not limited thereto. In the drawings, the thicknesses of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Further, throughout the specification, when it is referred to as “connected”, this does not only mean that two or more constituent elements are directly connected, but may mean that two or more constituent elements are indirectly connected through another constituent element, are physically connected, electrically connected, or are integrated even though two or more constituent elements are referred as different names depending on a location and a function.

Hereinafter, various exemplary embodiments and modifications will be described in detail with reference to the drawings.

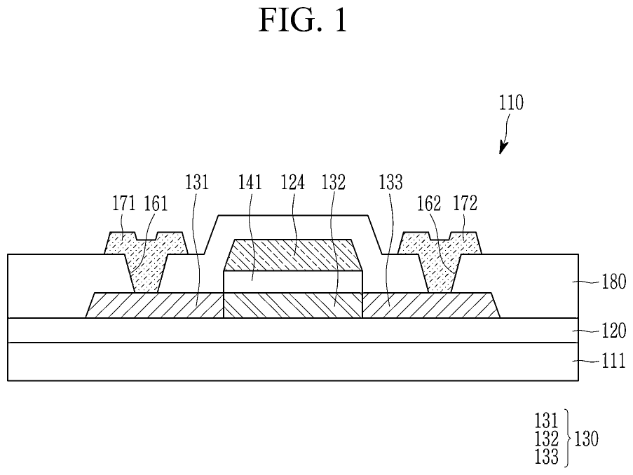

A thin film transistor according to an exemplary embodiment will be described with reference to FIG. 1. FIG. 1 is a cross-sectional view of a thin film transistor according to an exemplary embodiment.

Referring to FIG. 1, a thin film transistor 100 according to an exemplary embodiment includes a substrate 110. The substrate 110 may be a support substrate for supporting components to be described below, and be, for example, a glass plate, a polymer substrate, or a silicon wafer. The polymer substrate may be, for example, polyethylene terephthalate, polyethylene naphthalate, polycarbonate, polyacrylate, polymethyl methacrylate, polyimide, polyamide, polyamide-imide, a copolymer thereof, or a combination thereof, but is not limited thereto.

On the substrate 110, a buffer layer 120 is positioned. The buffer layer 120 may have a single-layer or multi-layer structure. In FIG. 1, the buffer layer 120 is shown as a single layer, but in some exemplary embodiments, the buffer layer may be composed of multiple layers.

The buffer layer 120 may contain an organic insulating material or an inorganic insulating material. As an example, the buffer layer 120 may contain at least one of silicon nitride (SiNₓ), silicon oxide (SiOₓ), and silicon oxynitride (SiOₓN_{y})

The thickness of the buffer layer 120 may be, for example, 100 nm to 1000 nm, and more specifically, 400 nm to 600 nm. The buffer layer 120 may prevent damage to the substrate 110 during a crystallization process on a semiconductor layer 130.

On the buffer layer 120, the semiconductor layer 130 is positioned. The semiconductor layer 130 may include a first region 131, a second region 132, and a third region 133. The first region 131, the second region 132, and the third region 133 may be differentiated according to whether each region is doped with impurities and the types of doped impurities. The first region 131 and the third region 133 may be doped with impurities, and the second region 132 may correspond to a channel region and contain polysilicon.

The thickness of the semiconductor layer 130 may be about 50 nm to about 800 nm, for example, about 50 nm to about 200 nm, but is not limited thereto. Further, the average grain size of the semiconductor layer 130 according to the exemplary embodiment may be about 50 nm to 200 nm. When the semiconductor layer 130 is thin, the buffer layer 120 may absorb the thermal energy of a blue laser. In contrast, as the thickness of the semiconductor layer 130 increases, the thermal energy can be sufficiently transferred to the semiconductor layer 130. Therefore, as the thickness of the semiconductor layer 130 increases, the average grain size of the semiconductor layer 130 can increase. As the grain size increases, traps which are caused by grain boundaries decrease, whereby high electron mobility can be secured. Therefore, the characteristics of the semiconductor layer can be improved.

The semiconductor layer 130 according to the exemplary embodiment may be formed by applying a blue laser annealing (abbreviated to BLA) method. In this case, the blue laser annealing method may be performed under an SPC condition. The SPC condition may be a condition that the power of a blue laser should be equal to or higher than 7 W and the scan speed of the blue laser is equal to or higher than 260 mm/s. As an example, the SPC condition may be a condition that the power of the blue laser is 7.5 W and the scan speed of the blue laser is 300 mm/s.

Herein, the BLA method refers to a process of irradiating an amorphous silicon thin-film with a laser beam using a blue laser with constant energy such that the amorphous silicon is crystallized at high temperature by the energy of the laser beam. The blue laser may have a maximum laser power of about 7 W to 14 W. Further, the blue laser may have a wavelength of about 400 nm to about 500 nm, for example, a wavelength of about 440 nm to about 450 nm. Furthermore, the scan speed of the blue laser may be about 200 mm/s to about 500 mm/s, for example, 260 mm/s to 300 mm/s.

The semiconductor layer according to the exemplary embodiment may be formed without a separate furnace by blue laser annealing such that a dehydrogenation process and a crystallization process may be performed at the same time. A specific manufacturing process will be described below. Furthermore, while an excimer laser annealing method which is generally used can crystallize a semiconductor layer with a maximum thickness of about 50 nm, the blue laser annealing method can crystallize even a relatively thicker semiconductor layer.

On the semiconductor layer 130, a gate insulating layer 141 may be positioned. The gate insulating layer 141 may contain an organic insulating material or an inorganic insulating material, and as an example, the gate insulating layer 141 may contain at least one of silicon nitride, silicon oxide, silicon oxynitride, and tetra ethyl ortho silicate (TEOS).

On the gate insulating layer 141, a gate electrode 124 is positioned. The gate electrode 124 may be positioned so as to overlap the second region 132 of the semiconductor layer 130, and the gate insulating layer 141 is positioned between the second region 132 of the semiconductor layer 130 and the gate electrode 124.

The gate electrode 124 may be a single-layer film containing at least one of copper (Cu), a copper alloy, aluminum (AI), an aluminum alloy, molybdenum (Mo), and a molybdenum alloy, or a multi-layer film consisting of metal films containing at least one of the above-mentioned materials.

On the gate electrode 124, a first insulating layer 180 is positioned. The first insulating layer 180 may contain an organic insulating material or an inorganic insulating material. As an example, the inorganic insulating material may contain at least one of silicon nitride, silicon oxide, silicon oxynitride, and tetra ethyl ortho silicate (TEOS). As an example, the organic insulating material may contain polyacrylates resin, polyimides resin, etc. In FIG. 1, the first insulating layer 180 is shown as a single layer, but is not limited thereto, and may be provided in a single-layer or multi-layer structure. As an example, the first insulating layer 180 may include a first layer containing silicon oxide, and a second layer containing silicon nitride.

The first insulating layer 180 may have a first contact hole 161 that overlaps the first region 131 of the semiconductor layer 130, and a second contact hole 162 that overlaps the third region 133 of the semiconductor layer 130.

On the first insulating layer 180, a source electrode 171 and a drain electrode 172 are positioned. The source electrode 171 is coupled to the first region 131 which is the source region of the semiconductor layer 130 by the first contact hole 161 of the first insulating layer 180, and the drain electrode 172 is coupled to the third region 133 which is the drain region of the semiconductor layer 130 by the second contact hole 162 of the first insulating layer 180.

The source electrode 171 and the drain electrode 172 may contain an aluminum-based metal, a silver-based metal, or a copper-based metal having low-specific resistance, and may be, for example, a triple-layer structure consisting of a lower film that contains a refractory metal such as titanium, molybdenum, chromium, tantalum, etc., or an alloy thereof, a middle film that contain an aluminum-based metal, a silver-based metal, or a copper-based metal having low-specific resistance, and an upper film that contains a refractory metal such as titanium, molybdenum, chromium, tantalum, etc.

The gate electrode 124, the source electrode 171, and the drain electrode 172 described above form a thin film transistor (TFT) together with the semiconductor layer 130, and the channel of the thin film transistor is formed in the second region 132 between the first region 131 and the third region 133 which are the source region and drain region of the semiconductor (131, 132, and 133), respectively.

The semiconductor layer according to the exemplary embodiment may be formed through a blue laser annealing process, such that dehydrogenation and crystallization of the semiconductor layer are performed at the same time. Accordingly, it is possible to provide a semiconductor layer manufactured through a simple process, and it is possible to provide a thin film transistor including such a semiconductor layer.

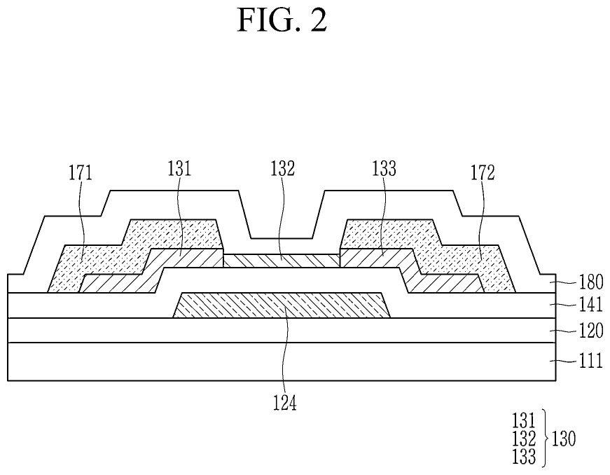

Hereinafter, a thin film transistor according to an exemplary embodiment will be described with reference to FIG. 2. FIG. 2 is a cross-sectional view related to a thin film transistor according to an exemplary embodiment. A description of components identical to the above-mentioned components may not be made.

Referring to FIG. 2, on a substrate 110, a buffer layer 120 may be positioned. On the buffer layer 120, a gate electrode 124 may be positioned, and on the gate electrode 124, a gate insulating layer 141 may be positioned.

The gate electrode 124 may be a single-layer film containing at least one of copper (Cu), a copper alloy, aluminum (AI), an aluminum alloy, molybdenum (Mo), and a molybdenum alloy, or a multi-layer film consisting of metal films containing at least one of the above-mentioned materials.

The gate insulating layer 141 may contain an organic insulating material or an inorganic insulating material, and as an example, the gate insulating layer 141 may contain at least one of silicon nitride, silicon oxide, silicon oxynitride, and tetra ethyl ortho silicate (TEOS).

On the gate insulating layer 141, a semiconductor layer 130 which includes a first region 131, a second region 132, and a third region 133 is positioned.

The semiconductor layer 130 may include a first region 131, a second region 132, and a third region 133. The first region 131, the second region 132, and the third region 133 may be differentiated according to whether each region is doped with impurities and the types of doped impurities. The first region 131 and the third region 133 may be doped with impurities, and the second region 132 may correspond to a channel region and contain polysilicon.

The thickness of the semiconductor layer 130 may be about 50 nm to about 800 nm, for example, about 50 nm to about 200 nm, but is not limited thereto. Further, the average grain size of the semiconductor layer 130 according to the exemplary embodiment may be about 50 nm to 200 nm. When the semiconductor layer 130 is thin, the buffer layer 120 may absorb the thermal energy of a blue laser. In contrast, as the thickness of the semiconductor layer 130 increases, the thermal energy can be sufficiently transferred to the semiconductor layer 130. Therefore, as the thickness of the semiconductor layer 130 increases, the average grain size of the semiconductor layer 130 can increase. As the grain size increases, traps which are caused by grain boundaries decrease, whereby high electron mobility can be secured. Therefore, the characteristics of the semiconductor layer can be improved.

The semiconductor layer 130 according to the exemplary embodiment may be formed by applying a blue laser annealing (abbreviated to BLA) method. In this case, the blue laser annealing method may be performed under an SPC condition. The SPC condition may be a condition that the power of a blue laser should be equal to or higher than 7 W and the scan speed of the blue laser is equal to or higher than 260 mm/s. As an example, the SPC condition may be a condition that the power of the blue laser is 7.5 W and the scan speed of the blue laser is 300 mm/s. In the SPC condition, the power of the blue laser may be set in such a range that the blue laser can melt the semiconductor layer.

Herein, the BLA method refers to a process of irradiating an amorphous silicon thin-film with a laser beam by a blue laser with constant energy such that the amorphous silicon is crystallized at high temperature by the energy of the laser beam. The blue laser may have a maximum laser power of about 7 W to 14 W, and may have a maximum laser power of about 7.5 W, for instance. Further, the blue laser may have a wavelength of about 400 nm to about 500 nm, for example, a wavelength of about 440 nm to about 450 nm. Furthermore, the scan speed of the blue laser may be about 200 mm/s to about 500 mm/s, for example, 260 mm/s to 300 mm/s.

The semiconductor layer according to the exemplary embodiment may be formed without a separate furnace by blue laser annealing such that a dehydrogenation process and a crystallization process may be performed at the same time. A specific manufacturing process will be described below. Furthermore, while an excimer laser annealing method which is generally used can crystallize a semiconductor layer with a maximum thickness of about 50 nm, the blue laser annealing method can crystallize even a relatively thicker semiconductor layer.

On the second region 132 which is the source region of the semiconductor layer 130, a source electrode 171 is positioned, and on the third region 133 which is the drain region of the semiconductor layer 130, a drain electrode 172 is positioned.

The source electrode 171 and the drain electrode 172 may contain an aluminum-based metal, a silver-based metal, or a copper-based metal having low-specific resistance, and may be, for example, a triple-layer structure consisting of a lower film that contains a refractory metal such as titanium, molybdenum, chromium, tantalum, etc., or an alloy thereof, a middle film that contain an aluminum-based metal, a silver-based metal, or a copper-based metal having low-specific resistance, and an upper film that contains a refractory metal such as titanium, molybdenum, chromium, tantalum, etc.

On the source electrode 171 and the drain electrode 172, the first insulating layer 180 is positioned. The first insulating layer 180 may contain an organic insulating material or an inorganic insulating material. As an example, the inorganic insulating material may contain at least one of silicon nitride, silicon oxide, silicon oxynitride, and tetra ethyl ortho silicate (TEOS). As an example, the organic insulating material may contain polyacrylates resin, polyimides resin, etc.

The gate electrode 124, the source electrode 171, and the drain electrode 172 described above form a thin film transistor together with the semiconductor layer 130, and the channel of the thin film transistor is formed in the second region 132 between the first region 131 and the third region 133 which are the source region and drain region of the semiconductor (131, 132, and 133), respectively.

The semiconductor layer according to the exemplary embodiment may be formed through a blue laser annealing process, such that dehydrogenation and crystallization of the semiconductor layer are performed at the same time, and may have a small grain size. Accordingly, it is possible to provide a semiconductor layer manufactured through a simple process, and it is possible to provide a thin film transistor including such a semiconductor layer.

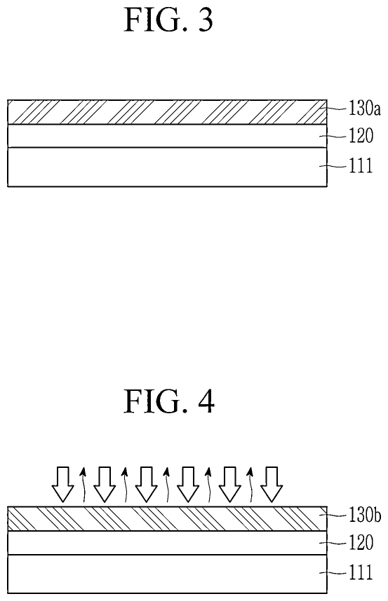

Hereinafter, a manufacturing method for a thin film transistor according to an exemplary embodiment will be described. FIG. 3 to FIG. 8 are cross-sectional views according to a manufacturing method for the thin film transistor according to an exemplary embodiment, respectively.

First, as shown in FIG. 3, on a substrate 110, a buffer layer 120 is stacked, and on the buffer layer 120, a hydrogenated amorphous silicon layer 130a is stacked.

The substrate 110 may be a support substrate for supporting components, and be, for example, a glass plate, a polymer substrate, or a silicon wafer. The polymer substrate may be, for example, polyethylene terephthalate, polyethylene naphthalate, polycarbonate, polyacrylate, polymethyl methacrylate, polyimide, polyamide, polyamide-imide, a copolymer thereof, or a combination thereof, but is not limited thereto.

The buffer layer 120 may have a single-layer or multi-layer structure. In FIG. 3, the buffer layer 120 is shown as a single layer, but in some exemplary embodiments, the buffer layer may be composed of multiple layers. The buffer layer 120 may contain an organic insulating material or an inorganic insulating material. As an example, the buffer layer 120 may contain at least one of silicon nitride (SiNₓ), silicon oxide (SiOₓ), and silicon oxynitride (SiOₓN_{y})

Subsequently, as shown in FIG. 4, a blue laser annealing (abbreviated to BLA) process is performed on the hydrogenated amorphous silicon layer 130a, such that a polysilicon layer 130b is formed.

The blue laser annealing process refers to a process of irradiating the hydrogenated amorphous silicon layer 130a with a laser beam by a blue laser with constant energy. At this time, the energy of the laser beam is used to perform a process of dehydrogenating the hydrogenated amorphous silicon layer 130a and perform a process of crystallizing the amorphous silicon at the same time.

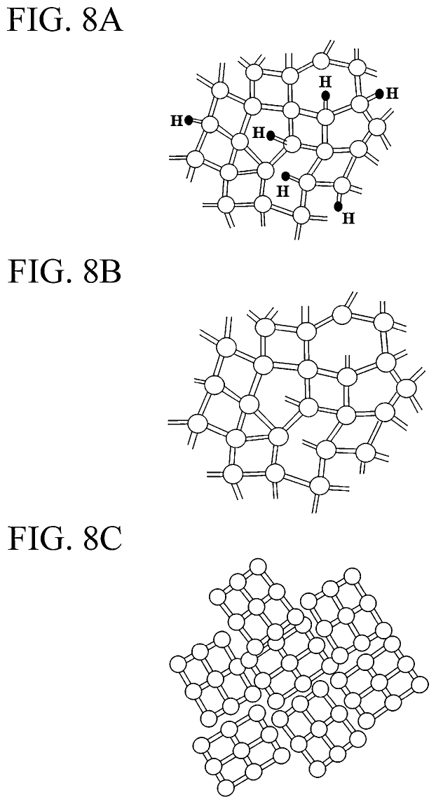

Referring to FIG. 8A, in FIG. 8A, the specific structure of the hydrogenated amorphous silicon layer 130a of FIG. 3 is shown. The amorphous silicon layer 130a has a form in which hydrogen atoms are randomly bonded between the bonds of silicon (Si) atoms (shown by white circles). Thereafter, in the blue laser annealing process, dehydrogenation in which hydrogen bonded to silicon is removed (see FIG. 8B) and crystallization in which the amorphous silicon is crystallized into polysilicon (see FIG. 8C) may be performed at the same time.

In the related art, a manufacturing process of moving the substrate with the hydrogenated amorphous silicon layer (see FIG. 8A) stacked thereon into a separate furnace, and performing dehydrogenation at a temperature of about 400 degrees to about 500 degrees (see FIG. 8B), and performing crystallization through an excimer laser annealing process or the like again (see FIG. 8C) has been used.

The above-mentioned blue laser annealing process may be performed at a temperature of about 950° C. or higher. The laser which is used in the blue laser annealing process may have a maximum laser power of about 7 W to 14 W, and may have a maximum laser power of about 7.5 W, for instance. Further, the laser which is used in the blue laser annealing process may have a wavelength of about 400 nm to about 500 nm, and may have a wavelength of about 440 nm to about 450 nm, for instance. Furthermore, the scan speed of the laser which is used in the blue laser annealing process may be about 200 mm/s to about 500 mm/s, and may be 260 mm/s to 300 mm/s, for instance.

In the step of performing blue laser annealing, the blue laser may scan the semiconductor layer one time to three times, and as an example, the amorphous silicon layer 130a may be dehydrogenated and crystallized by one scan of the blue laser.

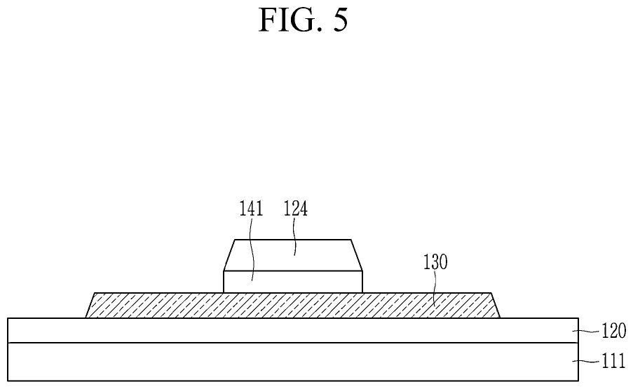

Subsequently, as shown in FIG. 5, a gate insulating layer 141 and a gate electrode 124 may be formed so as to overlap the channel region of the semiconductor layer 130 to be described below. The gate insulating layer 141 and the gate electrode 124 may be formed by sequentially stacking a gate insulating layer and a gate electrode layer on the semiconductor layer 130 and patterning them.

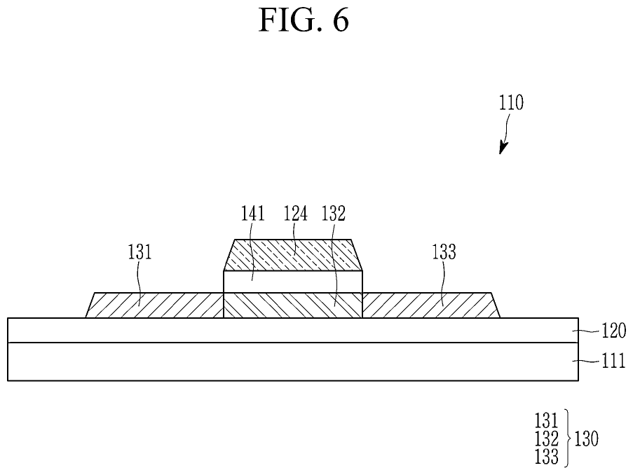

Next, as shown in FIG. 6, parts of the semiconductor layer which are exposed when the gate insulating layer 141 and the gate electrode 124 is used as a mask may be doped with impurities, whereby a first region 131 and a third region 133 may be formed. The part of the semiconductor layer 130 covered by the gate insulating layer 141 and the gate electrode 124 becomes a second region 132 corresponding to the channel region.

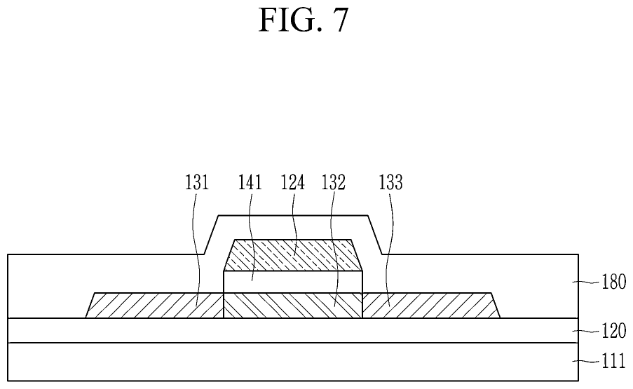

Subsequently, as shown in FIG. 7, on the gate electrode 124, a first insulating layer 180 is formed.

Next, in the first insulating layer 180, a first contact hole 161 and a second contact hole 162 may be formed so as to overlap the first region 131 and the second region 132, respectively. Subsequently, on the first insulating layer 180, a source electrode 171 and a drain electrode 172 may be formed, whereby a thin film transistor may be formed as shown in FIG. 1.

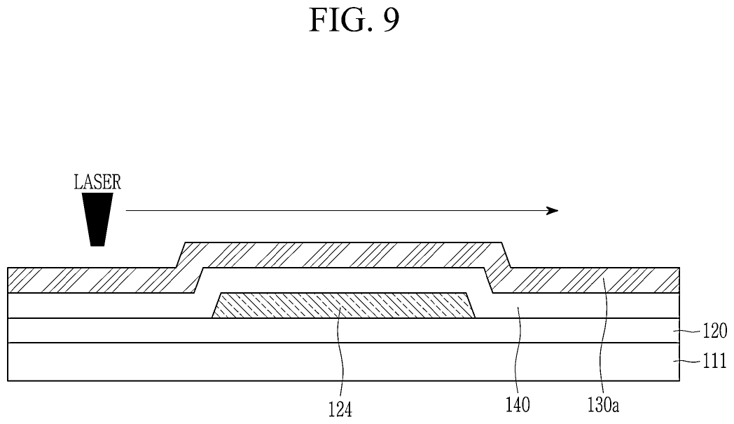

Hereinafter, a manufacturing method for a thin film transistor according to another exemplary embodiment will be described. FIG. 9 is a cross-sectional view according to a manufacturing method for a thin film transistor according to an exemplary embodiment. A description of components identical to the above-mentioned components will not be made.

Referring to FIG. 9, on a substrate 110, a buffer layer 120 and a gate electrode 124 are formed. Subsequently, a gate insulating layer 141 is formed so as to overlap the front surface of the substrate 110. Next, on the gate insulating layer 141, a hydrogenated amorphous silicon layer 130a is formed. Subsequently, as described above, a blue laser annealing process is performed on the hydrogenated amorphous silicon layer 130a, such that dehydrogenation and crystallization processes are performed at the same time. At this time, the blue laser annealing process which is performed under the SPC condition does not damage layers positioned below the semiconductor layer. Therefore, it is possible to provide a thin film transistor having a stable form.

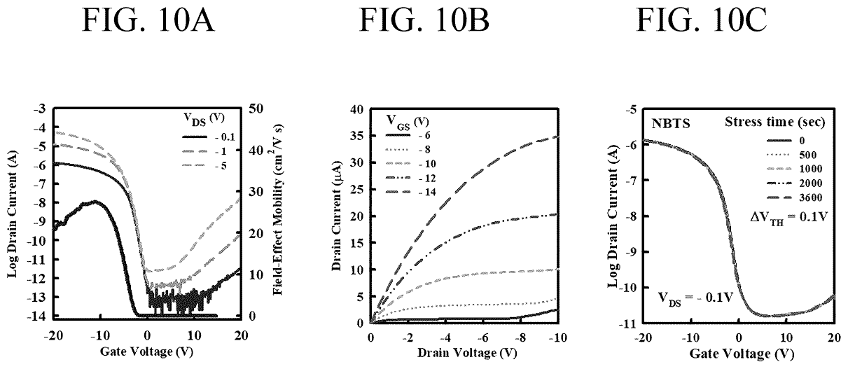

Hereinafter, the characteristics of a thin film transistor according to an exemplary embodiment will be described with reference to FIG. 10 to FIG. 18. FIG. 10 to FIG. 18 show experimental data of thin film transistors manufactured according to an exemplary embodiment.

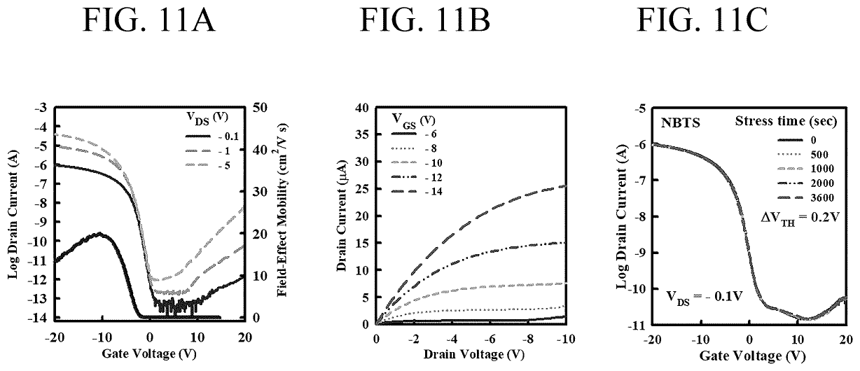

First, FIG. 10 shows experimental data of a thin film transistor manufactured according to a comparative example. The thin film transistor manufactured according to a comparative example was manufactured by putting a substrate with a hydrogenated amorphous silicon layer stacked thereon in a separate furnace, and performing a dehydrogenation process at 450 degrees for two hours, and performing a blue laser annealing process under a SPC condition. FIG. 11 shows experimental data of a thin film transistor manufactured by a manufacturing method according to an exemplary embodiment.

In FIG. 10A and FIG. 11A, drain current and field mobility depending on gate voltage are shown, and in FIG. 10B and FIG. 11B, drain current depending on drain voltage are shown, and FIG. 10C and FIG. 11C, drain current depending on gate voltage are shown. From them, mobility, threshold voltage V_{TH}, subthreshold swing value SS, and threshold voltage change value Δ V_{TH} were derived as shown in Table 1.

According to the derived values, it was confirmed that in the exemplary embodiment, mobility and threshold voltage change values substantially similar to those in the comparative example using a separate furnace were obtained and a subthreshold swing value better than that in the comparative example was obtained.

TABLE 1

| | Mobility | V_{TH} | SS | Stability |
|---|---|---|---|---|
| | (cm²/Vs) | (V) | (V/dec.) | (ΔV_{TH}) |
| Comparative | 27.6 | −1.3 | 0.67 | 0.1 |
| Example | | | | |
| Exemplary | 20.0 | −0.9 | 0.70 | 0.2 |
| Embodiment | | | | |

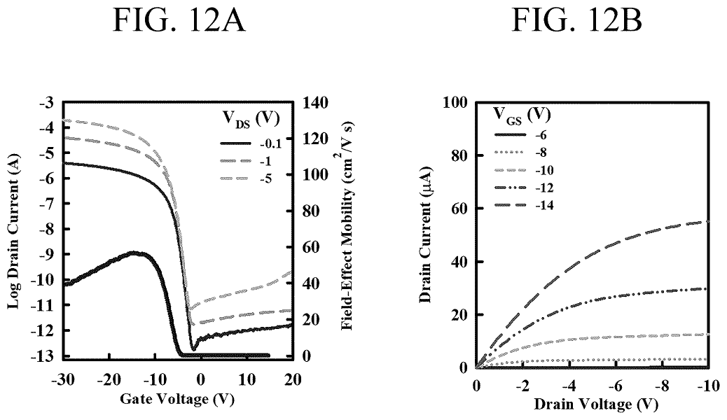

Further, FIG. 12A shows drain current and field mobility of a thin film transistor manufactured by the manufacturing method according to FIG. 9 depending on gate voltage, similar to FIG. 11A, and FIG. 12B shows drain current of the thin film transistor manufactured by the manufacturing method according to FIG. 9 depending on drain voltage, similar to FIG. 11B. From them, mobility, threshold voltage V_{TH}, and subthreshold swing value SS were derived as shown in the following Table 2. It could be seen that in the case of the thin film transistor manufactured by the manufacturing method according to FIG. 9, the mobility was greatly improved as compared to the comparative example of FIG. 10 and the subthreshold swing value was substantially the same as that in the comparative example.

TABLE 2

| | Mobility (cm²/Vs) | V_{TH} (V) | SS (V/dec.) |
|---|---|---|---|
| Comparative | 27.6 | −1.3 | 0.67 |
| Example | | | |
| Exemplary | 56.7 | −3.2 | 0.67 |
| Embodiment | | | |

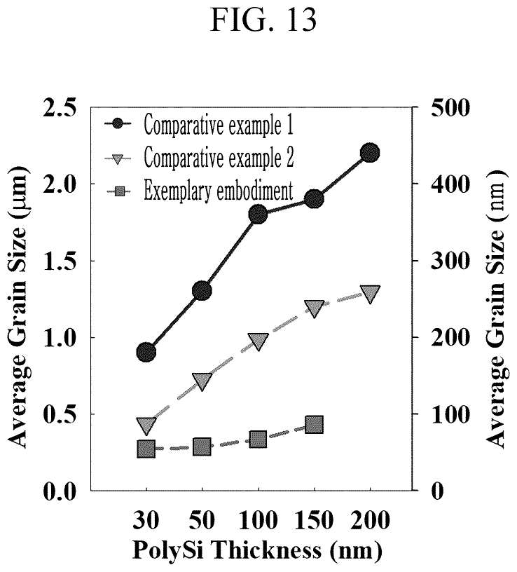

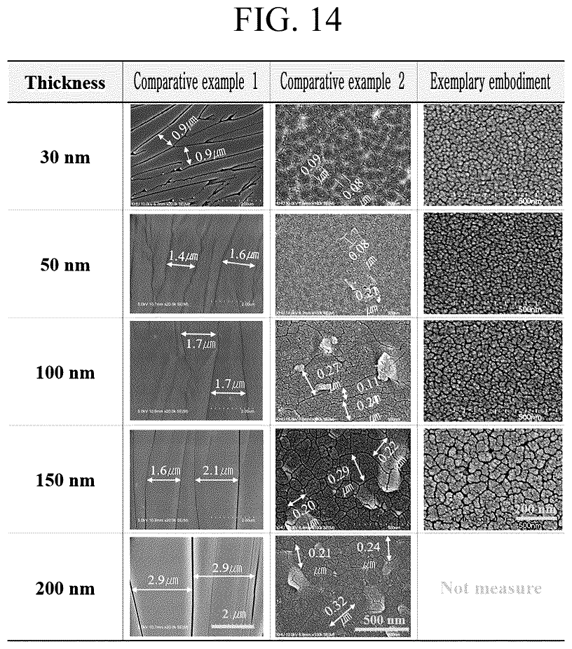

Furthermore, referring to FIG. 13 and FIG. 14, comparative example 1 used semiconductor layers subjected to a BLA process under a full melting condition, and comparative example 2 used semiconductor layers subjected to a BLA process under a partial melting condition, and an exemplary embodiment used semiconductor layers subjected to a BLA process under a SPC condition. Here, the full melting condition was a condition that the maximum laser power of a blue laser should be 11 W, and the partial melting condition was a condition that the maximum laser power of a blue laser should be 7.6 W to 10.9 W, and the SPC condition was a condition that the maximum laser power of a blue laser should be 7.5 W. Under each condition, the average grain sizes of hydrogenated amorphous silicon layers having different thicknesses were checked, and the results are shown in FIG. 13, FIG. 14, and Table 3.

TABLE 3

| Thickness of Hydrogenated | Comparative | Comparative | Exemplary |
|---|---|---|---|
| Amorphous Silicon Layer | Example 1 | Example 2 | Embodiment |
| 30 nm | 0.9 μm | 0.087 μm | 54 nm |
| 50 nm | 1.5 μm | 0.15 μm | 57 nm |
| 100 nm | 1.7 μm | 0.20 μm | 67 nm |
| 150 nm | 1.8 μm | 0.24 μm | 86 nm |
| 200 nm | 2.9 μm | 0.26 μm | — |

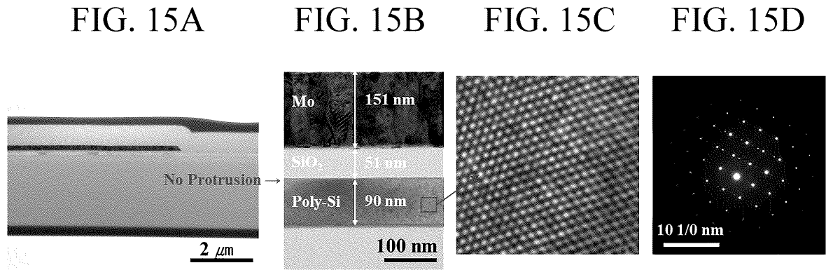

From the results, it was confirmed that when the blue laser annealing process was performed under the SPC condition according to the exemplary embodiment, as the thicknesses of the hydrogenated amorphous silicon layers increased from 30 nm to 150 nm, the average grain sizes increased from 54 nm to 86 nm. In contrast, it was confirmed that in comparative example 1 in which the blue laser annealing process was performed under the full melting condition, as the thicknesses of the hydrogenated amorphous silicon layers increased from 30 nm to 200 nm, the average grain sizes increased from about 1 μm to about 3 μm. It was confirmed that in comparative example 2 in which the blue laser annealing process was performed under the partial melting condition, as the thicknesses of the hydrogenated amorphous silicon layers increased from 50 nm to 200 nm, the average grain sizes increased from about 0.15 μm to about 0.26 μm. In other words, it was confirmed that although blue laser annealing processes are used similarly, grain sizes may differ depending on conditions, and in particular, when an SPC condition is applied, similarly in the exemplary embodiment, it is possible to provide a semiconductor layer having a relatively smaller average grain size. FIG. 15A shows a TEM cross-sectional image of a semiconductor layer according to comparative example 1 (a semiconductor layer manufactured under the full melting condition), and FIG. 15B shows an enlarged image of FIG. 15A, and FIG. 15C shows an enlarged image of the rectangle in FIG. 15B. FIG. 15D shows a selected area electron diffraction (SAED) image.

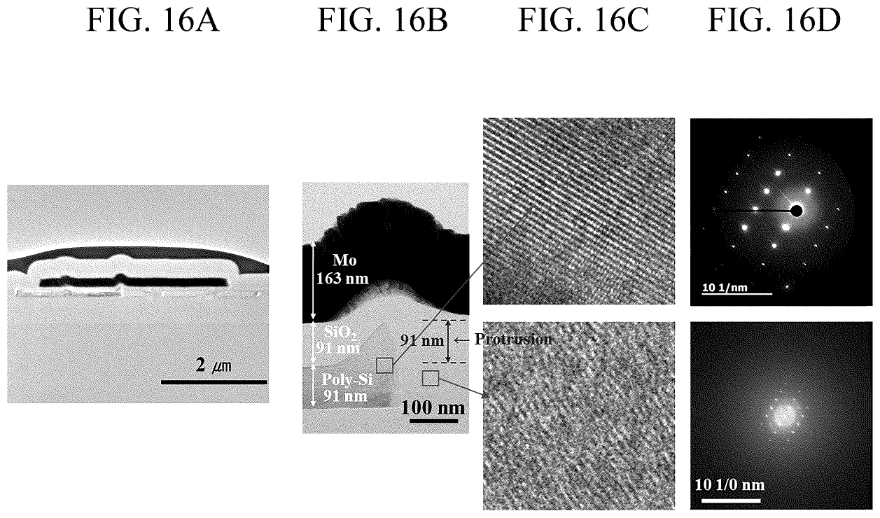

FIG. 16A shows a TEM cross-sectional image of a semiconductor layer according to comparative example 2 (a semiconductor layer manufactured under the partial melting condition), and FIG. 16B shows an enlarged image of FIG. 16A, and FIG. 16C shows enlarged images of the rectangles in FIG. 16B. FIG. 16D shows selected area electron diffraction (SAED) images.

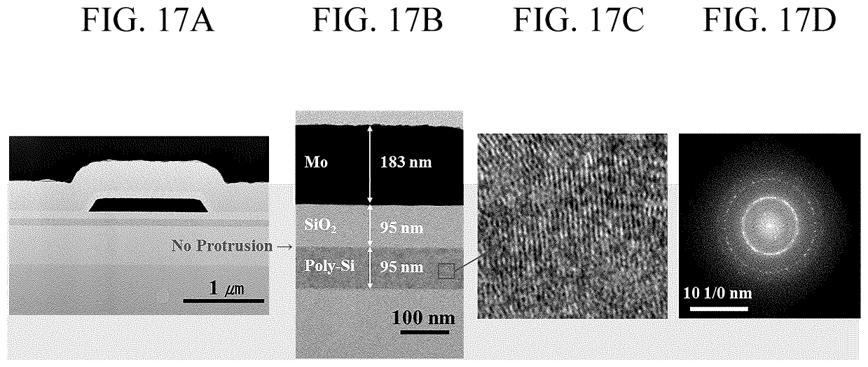

FIG. 17A shows a TEM cross-sectional image of a semiconductor layer according to the exemplary embodiment (a semiconductor layer manufactured under the SPC condition), and FIG. 17B shows an enlarged image of FIG. 17A, and FIG. 17C shows an enlarged image of the rectangle in FIG. 17B. FIG. 17D shows a selected area electron diffraction (SAED) image.

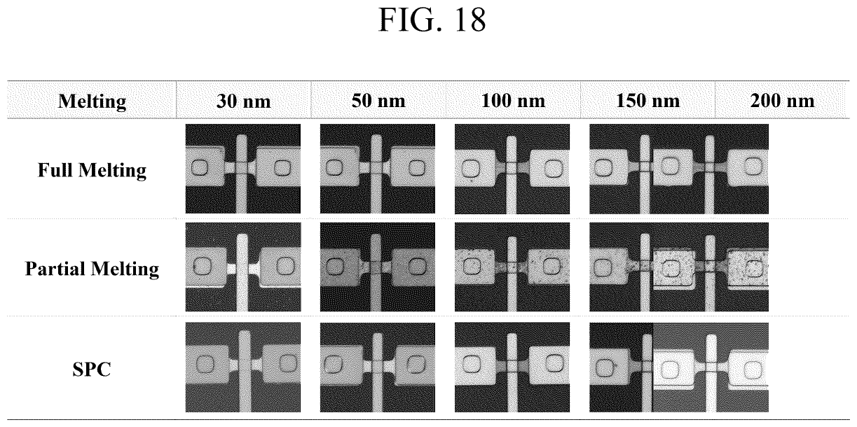

From the images in FIG. 17, it can be seen that the semiconductor layer was formed so as to have a flat surface without separate protrusions, and the flatness of the flat surface was similar to that in comparative example 1 shown in FIG. 15. In contrast, it was confirmed that comparative example 2 in FIG. 16 was manufactured in a somewhat unstable form with protrusions. From the images in FIG. 18, it could be confirmed that in comparative example 2, the semiconductor layers were manufactured in unstable forms with a number of protrusions, like stains, but in comparative example 1 and the exemplary embodiment, the semiconductor layers were manufactured in smooth forms without protrusions or stains.

While this invention has been described in connection with what is presently considered to be practical exemplary embodiments, it is to be understood that the invention is not limited to the disclosed exemplary embodiments. On the contrary, it is intended to cover various modifications and equivalent arrangements included within the spirit and scope of the appended claims.

### DESCRIPTION OF SYMBOLS

110: Substrate
120: Buffer layer
130: Semiconductor layer
131: First region
132: Second region
133: Third region
161, 162: Contact hole
181: First electrode
182: Second electrode

What is claimed is:

1. A manufacturing method for a thin film transistor, the method comprising:
a step of forming a buffer layer on a substrate;
a step of forming a hydrogenated amorphous silicon layer on the buffer layer;
a step of performing blue laser annealing on the hydrogenated amorphous silicon layer; and
a step of forming a semiconductor layer by doping parts of the hydrogenated amorphous silicon layer with impurities, wherein
in the step of performing blue laser annealing, dehydrogenation and crystallization are performed in the hydrogenated amorphous silicon layer.

2. The manufacturing method for the thin film transistor according to claim 1, wherein
the dehydrogenation and the crystallization are performed at the same time.

3. The manufacturing method for the thin film transistor according to claim 1, wherein
in the step of performing blue laser annealing, a blue laser scans the semiconductor layer one time to three times.

4. The manufacturing method for the thin film transistor according to claim 1, wherein
the power of a blue laser which is used in the step of performing blue laser annealing is 7 W or higher.

5. The manufacturing method for the thin film transistor according to claim 1, wherein
a blue laser which is used in the step of performing blue laser annealing has a wavelength range from 400 nm to 500 nm.

6. The manufacturing method for the thin film transistor according to claim 5, wherein
the blue laser which is used in the step of performing blue laser annealing has a wavelength range from 440 nm to 450 nm.

7. The manufacturing method for the thin film transistor according to claim 3, wherein
the scan speed of the blue laser is 200 mm/s to 500 mm/s.

8. The manufacturing method for the thin film transistor according to claim 7, wherein
the step of performing blue laser annealing is performed at 950° C. or higher.

9. The manufacturing method for the thin film transistor according to claim 1, wherein
the average grain size of the semiconductor layer formed through the blue laser annealing is 50 nm to 200 nm.

10. The manufacturing method for the thin film transistor according to claim 9, wherein
the thickness of the semiconductor layer is 50 nm to 800 nm.

11. The manufacturing method for the thin film transistor according to claim 1, further comprising:
a step of forming a gate electrode so as to overlap the semiconductor layer.

12. A thin film transistor that is manufactured by the manufacturing method according to claim 1.

13. The thin film transistor of claim 12, wherein
the thin film transistor includes the following:
a semiconductor layer that includes a first region, a second region, and a third region;
a gate electrode that overlaps the second region of the semiconductor layer;
a source electrode that is electrically coupled to the first region; and
a drain electrode that is electrically coupled to the third region, and
the average grain size of the semiconductor layer is 50 nm to 200 nm.

14. The thin film transistor of claim 13, wherein
the thickness of the semiconductor layer is 50 nm to 800 nm.

15. The thin film transistor of claim 13, wherein
the gate electrode is positioned on the semiconductor layer, and
the thin film transistor further includes a gate insulating layer that is positioned between the gate electrode and the semiconductor layer.

16. The thin film transistor of claim 13, wherein
the gate electrode is positioned between the semiconductor layer and the substrate, and
the thin film transistor further includes a gate insulating layer that is positioned between the gate electrode and the semiconductor layer.

17. The thin film transistor of claim 13, wherein
the semiconductor layer contains polysilicon.

18. The thin film transistor of claim 13, wherein
the substrate contains polyimide.
